(19) United States
(12) Patent Application Publication
(10) Pub. No.: US 2026/0247741 A1
(43) Pub. Date: Aug. 20, 2026

(54) NANO-JANUS PHOTOCATALYST FOR CO2 REDUCTION AND METHOD FOR FABRICATING THE SAME

(71) Applicants: Sui YANG, Chandler, AZ (US); Shuai Feng, Tempe, AZ (US); Jaewoo Park, Tempe, AZ (US); Abhishek Kumar, Tempe, AZ (US)

(72) Inventors: Sui YANG, Chandler, AZ (US); Shuai Feng, Tempe, AZ (US); Jaewoo Park, Tempe, AZ (US); Abhishek Kumar, Tempe, AZ (US)

(73) Assignee: Arizona Board of Regents on Behalf of Arizona State University, Scottsdale, AZ (US)

(21) Appl. No.: 19/540,033

(22) Filed: Feb. 13, 2026

Related U.S. Application Data
(60) Provisional application No. 63/758,720, filed on Feb. 14, 2025.

(51) Int. Cl. H10F 77/14; B01J 35/39; H10F 71/00

(52) U.S. Cl. CPC H10F 77/143; B01J 35/39; H10F 71/00

(57) ABSTRACT

A nano-Janus photocatalyst for CO2 reduction and method for fabricating the same is disclosed. The photocatalyst includes a plurality of nanoparticles, each nanoparticle having a plasmonic metal coupled to a semiconductor to form a nano-Janus heterostructure. An interface between the plasmonic metal and the semiconductor forms a Schottky junction. The plasmonic metal may be gold, and the semiconductor may be Cu2O. A method for fabricating the nano-Janus photocatalyst includes tuning a surface energy of a plurality of plasmonic metal nanoscale seeds through ligand incubation, and deposing a semiconductor on part of each seed, with the semiconductor growing on the seed through selective nucleation informed by the ligand incubation.

### RELATED APPLICATIONS

This application claims the benefit of U.S. Provisional Patent Application No. 63/758,720, filed Feb. 14, 2025, titled “Nano-Janus Photocatalyst for CO₂ Reduction and Method for Fabricating the Same,” the entirety of which is incorporated herein by reference.

### TECHNICAL FIELD

The present disclosure relates generally to photocatalytic materials and methods of fabrication. More specifically, it relates to nano-Janus heterostructures comprising plasmonic metals and semiconductors for carbon dioxide (CO₂) reduction.

### BACKGROUND

CO₂ emissions significantly contribute to global warming and climate change, impacting the environment, public health, and economic sectors. Major sources include electricity generation from fossil-fuel power plants, transportation dominated by internal combustion engines, and industrial processes such as cement and chemical production. Residential and commercial activities, including heating and cooling, also add to the carbon footprint, underscoring the need for comprehensive emission-reduction strategies.

Technologies for reducing CO₂ emissions include carbon capture and storage, which traps CO₂ using specialized materials. However, long-term storage poses challenges such as potential secondary emissions. Converting CO₂ into useful products offers a promising alternative, but its chemical stability makes conversion difficult.

Existing CO₂ conversion methods—electrochemical, thermal, and radiolysis—are energy-intensive and environmentally unfriendly. Photocatalytic CO₂ conversion has emerged as a green alternative, but efficiency remains limited by challenges in light absorption and charge carrier separation.

### SUMMARY

In some embodiments, a photocatalyst for CO₂ reduction includes a plurality of nanoparticles. Each nanoparticle has a plasmonic metal coupled to a semiconductor to form a nano-Janus heterostructure. The interface between the plasmonic metal and the semiconductor forms a Schottky junction. In some embodiments, the plasmonic metal comprises gold. In some embodiments, the semiconductor comprises cuprous oxide (Cu₂O). In certain embodiments, the plasmonic metal and semiconductor portions are joined along a planar interface. In other embodiments, the plasmonic metal and semiconductor portions are joined along a curved interface. In some embodiments, the nanoparticles have a geometry selected from spherical, cubic, or dodecahedral.

In some embodiments, a system for CO₂ reduction includes a reactor chamber configured to receive CO₂ and light energy, and a photocatalyst disposed within the reactor chamber. The photocatalyst comprises a plurality of nanoparticles, each nanoparticle including a plasmonic metal coupled to a semiconductor to form a nano-Janus heterostructure with a Schottky junction at the interface between the metal portion and the semiconductor portion. In some embodiments, the photocatalyst comprises a substrate configured to orient the nanoparticles in a predetermined direction. According to some embodiments, the nanoparticles are embedded in a porous matrix that maintains alignment of the plasmonic metal and semiconductor portions. In some embodiments, the photocatalyst comprises a substrate having surface features that orient the nanoparticles. In certain embodiments, the nanoparticles are oriented in the same direction. In some embodiments, the substrate includes a conductive layer configured to electrically couple to the plasmonic metal portions of the nanoparticles. In some embodiments, the nanoparticles are immobilized on the substrate using a ligand-based anchoring system that preserves the nano-Janus configuration. According to some embodiments, the photocatalyst comprises a three-dimensional scaffold configured to support the nanoparticles in multiple orientations.

In some embodiments, a method for fabricating a photocatalyst for CO₂ reduction includes tuning a surface energy of a plurality of plasmonic metal nanoscale seeds through ligand incubation, depositing a semiconductor on part of each seed, and growing the semiconductor on the seed through selective nucleation informed by the ligand incubation. In some embodiments, the plasmonic metal comprises gold (Au). In some embodiments, the semiconductor comprises cuprous oxide (Cu₂O). In some embodiments, tuning the surface energy of the plasmonic metal nanoscale seeds comprises exposing the seeds to a thiol-based ligand solution. In certain embodiments, depositing the semiconductor comprises solution-phase deposition. In some embodiments, the semiconductor material is deposited on a portion of each seed such that the semiconductor material grows selectively on the seed to form a nano-Janus heterostructure.

The foregoing and other aspects, features, and advantages will be apparent from the DESCRIPTION, DRAWINGS, and CLAIMS.

### BRIEF DESCRIPTION OF THE DRAWINGS

Implementations will hereinafter be described in conjunction with the appended and/or included DRAWINGS, where like designations denote like elements, and:

FIG. 1 shows a schematic of a nano-Janus photocatalyst according to some embodiments.

FIG. 2 shows a flowchart of steps for fabricating a nano-Janus photocatalyst according to some embodiments.

FIG. 3 shows a reactor system for CO₂ reduction incorporating a nano-Janus photocatalyst according to some embodiments.

### DETAILED DESCRIPTION

The following detailed description provides numerous specific details. Those skilled in the relevant arts understand that embodiments of the disclosure may be practiced without these specific details. The disclosure may also be practiced in different and alternative configurations.

Unless specifically noted, it is intended that the words and phrases in the specification and the claims be given their plain, ordinary, and accustomed meaning to those of ordinary skill in the applicable arts. The singular forms “a,” “an,” and “the” include plural referents unless the context clearly dictates otherwise. Thus, for example, a reference to “a step” includes a reference to one or more of such steps. The words “exemplary,” “example,” “embodiment,” or various forms thereof are used herein to mean serving as an example, instance, or illustration. Any aspect or feature described herein as “exemplary” or as an “example” is not necessarily to be construed as preferred or advantageous over other aspects or designs. The examples are provided solely for purposes of clarity and understanding and do not limit or restrict the disclosure. It is to be appreciated that a myriad of additional or alternate examples of varying scope could have been presented, but have been omitted for purposes of brevity.

Throughout the description and claims of this specification, the words “comprise” and “contain” and variations of the words, for example “comprising” and “comprises”, mean “including but not limited to”, and are not intended to (and do not) exclude other components.

When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions. The term “plurality”, as used herein, means more than one.

The present disclosure is directed to nano-Janus photocatalysts for solar carbon dioxide photoconversion, and methods for fabricating the same. Embodiments of the disclosed nano-Janus photocatalysts provide superior light absorption and more efficient separation of photogenerated carriers compared to conventional photocatalysts.

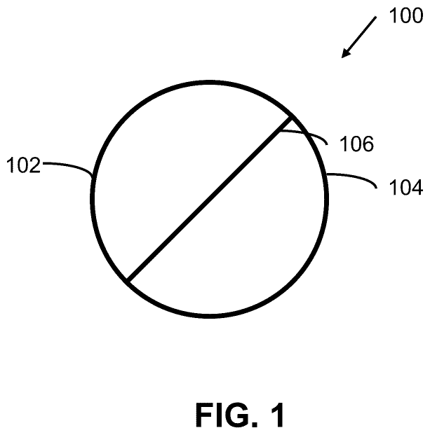

FIG. 1 shows a schematic of a nano-Janus photocatalyst 100, according to some embodiments. Nano-Janus photocatalyst 100 has two portions: plasmonic metal 102 and semiconductor 104. Plasmonic metal 102 and semiconductor 104 are joined to each other at interface 106. These “two-faced” nano-Janus photocatalysts 100 harness a synergy between the two materials (e.g., metal and oxide resonances, etc.). Plasmonic light confinement from plasmonic metal 102 enhances solar light absorption through localized electromagnetic fields. The metal-semiconductor interface forms a Schottky junction at interface 106 that separates electrons and holes, facilitating charge transfer for CO₂ reduction and efficient solar-to-energy conversion.

In some embodiments, plasmonic metal 102 may be gold (Au). Gold nanoparticles are known for their strong absorption of resonant light through localized surface plasmon resonance (LSPR). This property enables the confinement of light energy at the nanoscale, thereby enhancing the absorption of solar light. In other embodiments, a different metal may be used.

In some embodiments, semiconductor 104 may be cuprous oxide (Cu₂O). Cu₂O is a promising photocatalyst for CO₂ reduction due to its excellent chemisorption properties, multi-electron transfer pathways, and low electron affinity. Additionally, Cu₂O is a low-cost, direct-gap semiconductor with a bandgap of approximately 2.1 eV, enabling the absorption of a large portion of visible light.

Embodiments of the disclosed nano-Janus photocatalyst leverage the synergistic interaction between gold (Au) and cuprous oxide (Cu₂O) within the same nanoparticle, each providing a “face” that enable simultaneously enhanced light absorption and photocarriers generation (and separation) for highly efficient CO₂ reduction. The interaction between the plasmonic resonance of Au and the Mie resonance of Cu₂O enhances the overall light absorption by creating multiple optical modes that cover a broad spectrum of solar light. The hybrid plasmonic-Mie nanoantenna structure ensures that the electromagnetic field is highly localized, leading to significant light confinement and enhanced absorption efficiency. Additionally, the interface between Au (metal) and Cu₂O (semiconductor) forms a unique Schottky junction. This junction facilitates the separation of photogenerated electrons (e−) and holes (h+), enhancing the efficiency of charge transfer and CO₂ reduction, overcoming the limitations of existing photocatalysts.

While the synergy between these two materials (Au and Cu₂O) makes this particular nano-Janus photocatalyst perform particularly well (as will be discussed below), it should not be taken as a limitation. In other embodiments, different materials may be used for the plasmonic metal and/or semiconductor, which may result in different efficiencies and/or may adapt the photocatalyst for use in specific environments or to absorb a different, more specific part of the spectrum.

The design ensures strong optical coupling between the plasmonic and Mie resonances. This coupling generates multipole electric and magnetic responses across optical frequencies, leading to enhanced light absorption and carrier separation. The contemplated nano-Janus structure enhances light absorption across a broad spectrum of solar light, making it highly efficient in utilizing natural sunlight for CO₂ conversion. This broad-spectrum absorption capability is a significant improvement over existing photocatalysts that often focus on narrow wavelength ranges. Moreover, it makes the process highly energy-efficient and cost-effective compared to traditional methods such as electrochemical, thermal, and radiolysis, which require external energy inputs.

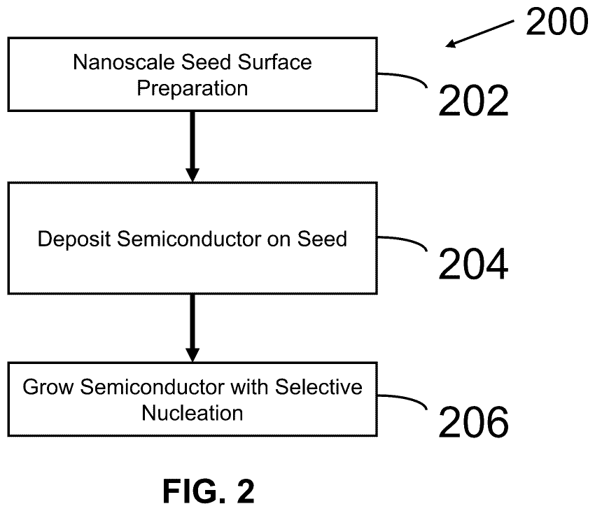

FIG. 2 shows a flowchart 200 showing a method of making a nano-Janus photocatalyst, according to some embodiments. The fabrication of the nano-Janus photocatalyst begins with the surface preparation of nanoscale “seeds” 202 composed of the plasmonic metal, for example, Au. The surface of the nanoscale seed is prepared by manipulating the surface energy through ligand incubation. Manipulating these surface energies permits a degree of control over the interaction between the seed and precursors of the semiconductor.

Once the desired portion of the seed's surface is prepared, the semiconductor (e.g., Cu₂O) is deposited on part of the seed 204 (per the ligand incubation). According to various embodiments, the semiconductor grows on the seed through selective nucleation 206 driven, at least in part, by the ligand incubation.

The nano-Janus photocatalysts disclosed herein offer an additional advantage over conventional systems. Specifically, adjusting nanoparticle geometry and size can maximize light absorption and carrier separation—customization not typically achievable in existing technologies. The nano-Janus photocatalyst design incorporates optimization of Au and Cu₂O nanoparticle geometry and dimensions to achieve superior performance. Predictive modeling techniques, including finite-element method (FEM) and Mie theory-based numerical simulations, may be employed to evaluate optical properties and overall performance of the composite structure.

As a non-limiting example, FEM and Mie simulations may be used to calculate absorption spectra and electromagnetic field distributions for Au-Cu₂O nano-Janus structures. Iterative feedback from these simulations can identify optimal geometries and sizes for maximizing light absorption and carrier separation. Multipole simulations may also be performed to analyze electric and magnetic multipole responses, providing insight into mechanisms of light confinement and absorption enhancement.

According to various embodiments, nanoparticle shape and size can optimize optical absorption and charge separation. Geometries under consideration include, but are not limited to, spherical, cubic, and dodecahedral configurations. Simulation data informs the impact of geometry and size on absorption cross-sections and carrier separation efficiency, guiding selection of the most effective configuration.

Embodiments of the disclosed nano-Janus photocatalyst provide advantages over conventional carbon capture technologies. Not only are the systems more efficient, but they can also operate with lower capital and operational costs.

In some embodiments, a device configured for photocatalytic CO₂ reduction may include a reactor structure adapted to expose the nano-Janus photocatalyst to incident light while permitting controlled contact between the catalyst and a CO₂-containing medium. The reactor may take the form of a slurry-phase photoreactor in which the photocatalyst is dispersed in an aqueous or mixed solvent system saturated with CO₂. In other embodiments, the reactor may comprise an immobilized-film architecture in which the photocatalyst is deposited upon a transparent or conductive substrate positioned to receive illumination. Still further embodiments may utilize a flow-through photoreactor that incorporates one or more channels or chambers through which CO₂-saturated liquid or humidified gaseous CO₂ may pass while the photocatalyst resides on illuminated internal surfaces.

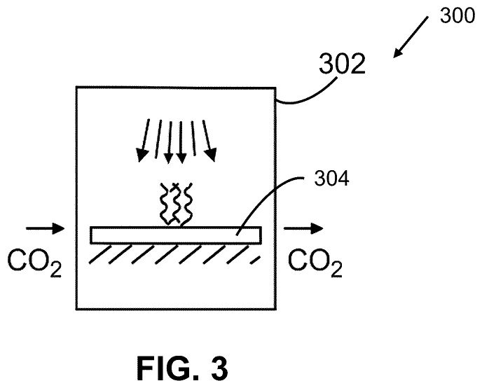

FIG. 3 shows a schematic of a reactor system 300 for CO₂ reduction. Reactor system 300 includes reactor 302 and substrate 304. Substrate 304 contains a nano-Janus photocatalyst. Substrate 304 is exposed to a stream of CO₂ and light.

In some embodiments, the photocatalyst may be integrated into the device by depositing the nano-Janus particles onto a substrate using techniques such as drop-casting, spin-coating, spray-coating, or dip-coating. These methods may allow the nanoparticles to form a uniform catalytic layer without substantially degrading the plasmonic-semiconductor heterostructure. In other embodiments, the photocatalyst may be immobilized through layer-by-layer assembly techniques, in which alternating layers of catalyst and binding materials form a mechanically robust film. Additional embodiments may incorporate the photocatalyst into porous matrices, membranes, or aerogels, thereby increasing catalyst exposure to CO₂ and enabling improved mass-transfer characteristics.

In some embodiments, the substrate upon which the photocatalyst is deposited may include glass, quartz, sapphire, silicon, or transparent conductive oxides (e.g., fluorine-doped tin oxide or indium tin oxide). Such substrates may be selected for their optical transparency, chemical stability, or ability to serve as charge-collecting electrodes when photoelectrochemical configurations are employed. In other embodiments, metallic substrates or polymeric supports may be used when the reactor geometry favors flexible, curved, or modular components. These substrates may additionally include surface treatments or adhesion-promoting layers to ensure durable bonding of the nano-Janus photocatalyst under extended operational conditions.

In some embodiments, the device may include one or more illumination systems configured to deliver light of appropriate wavelength and intensity to the photocatalyst. Such systems may comprise natural sunlight, concentrated sunlight, light-emitting diodes, laser diodes, or broadband lamps. The device may further include optical elements such as focusing lenses, reflective surfaces, waveguides, diffusers, or anti-reflection coatings to enhance uniformity and efficiency of light absorption. In embodiments where the plasmonic metal component of the photocatalyst is engineered to enhance localized electromagnetic fields, the geometry of the illumination path may be optimized to maximize resonance coupling and improve photocatalytic efficiency.

In some embodiments, the device may include a CO₂ delivery subsystem that regulates the introduction of CO₂ gas or CO₂-containing mixtures into the reactor. This subsystem may incorporate mass-flow controllers, diffusers, bubbling stones, microporous membranes, or other components designed to achieve uniform CO₂ dispersion across the photocatalyst. In certain embodiments, a gas-liquid contacting interface may be used, in which CO₂ is dissolved into a liquid phase that contacts the catalyst surface. In other embodiments, humidified gaseous CO₂ may flow directly over a catalyst film, thereby limiting mass-transfer resistance associated with aqueous dissolution. Flow-through channels, fluidic manifolds, or membrane contactors may be included to maintain consistent reactant delivery and remove accumulated reaction products.

In some embodiments, the device may include product-collection components configured to isolate reaction products such as methane, carbon monoxide, formate, methanol, or other carbon-based fuels generated by the photocatalytic process. Gas-phase products may be collected in a sealed headspace and routed through valves or sampling ports, while liquid-phase products may be harvested from the reactor effluent or through an integrated recirculating loop. In additional embodiments, the device may optionally include one or more electrodes that facilitate charge extraction or improve electron-hole separation within the photocatalyst layer, thereby enhancing performance. Such hybrid photoelectrochemical configurations may incorporate conductive backings, counterelectrodes, membranes, or external circuitry while maintaining the fundamentally photocatalytic operation of the nano-Janus system.

In certain implementations, the semiconductor portion (e.g., Cu2O) may be susceptible to chemical or photoinduced degradation under photocatalytic operating conditions, including (by way of example) changes in oxidation state or phase at or near the semiconductor surface when photogenerated carriers are not efficiently extracted or consumed by desired reaction pathways. Accordingly, in some embodiments the disclosed nano-Janus heterostructure is configured to mitigate such degradation by promoting directional charge separation and charge extraction. For example, the Schottky junction formed at the interface between the plasmonic metal portion and the semiconductor portion may create an internal field that inhibits electron-hole recombination and biases charge transfer across the interface. In certain embodiments, the plasmonic metal portion of the nano-Janus particle is electrically coupled (directly or indirectly) to a conductive layer of a substrate, thereby providing an electron-collection pathway through the metal portion while leaving the semiconductor portion available for adsorption and activation of CO2. In further embodiments, the nano-Janus particles are oriented (e.g., aligned in a common direction) so that the plasmonic metal portions preferentially face and/or contact the conductive layer and/or are otherwise positioned to facilitate selective carrier transport, which can reduce carrier accumulation within the semiconductor portion and improve operational durability.

Additionally or alternatively, stability of the semiconductor portion may be enhanced through optional passivation, protective, or cocatalyst structures. In some embodiments, the semiconductor portion and/or the composite nano-Janus particle is provided with a conformal or partial protective overlayer comprising a metal oxide or other chemically stable material (e.g., a thin TiO2, Al2O3, SiO2, ZnO, or other metal oxide layer), which may inhibit direct chemical attack by the reaction medium while permitting carrier tunneling and/or interfacial charge transfer. In some embodiments, an oxidation cocatalyst, hole-accepting material, or hole scavenger is provided to preferentially consume photogenerated holes and thereby suppress semiconductor self-oxidation; additionally or alternatively, a reduction cocatalyst, electron-accepting material, or reaction condition is provided to preferentially consume photogenerated electrons and thereby suppress semiconductor self-reduction. Non-limiting examples include depositing cocatalyst nanoparticles on the semiconductor face, introducing redox mediators, adjusting electrolyte composition and/or pH, removing dissolved oxygen, operating in a gas-phase or humidified CO2 environment, and/or controlling illumination intensity and/or duty cycle. The foregoing stabilization features may be used alone or in combination with the nano-Janus heterostructure, and may be selected according to the desired reaction products, reactor architecture (slurry, immobilized film, or flow-through), and operating environment.

More specifically, this disclosure, its aspects and embodiments, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

Many additional implementations are possible. Further implementations are within the CLAIMS.

It will be understood that implementations of the preceding disclosure include but are not limited to the specific components disclosed herein, as virtually any components consistent with the intended operation may be utilized. Accordingly, for example, it should be understood that, while the drawings and accompanying text show and describe particular implementations, any such implementation may comprise any shape, size, style, type, model, version, class, grade, measurement, concentration, material, weight, quantity, and/or the like consistent with the intended operation.

The concepts disclosed herein are not limited to the specific embodiments shown herein. For example, it is specifically contemplated that the components included in particular embodiments may be formed of any of many different types of materials or combinations that can readily be formed into shaped objects and that are consistent with the intended operation of the disclosure. For example, the components may be formed of: rubbers (synthetic and/or natural) and/or other like materials; glasses (such as fiberglass), carbon-fiber, aramid-fiber, any combination therefore, and/or other like materials; elastomers and/or other like materials; polymers such as thermoplastics (such as ABS, fluoropolymers, polyacetal, polyamide, polycarbonate, polyethylene, polysulfone, and/or the like, thermosets (such as epoxy, phenolic resin, polyimide, polyurethane, and/or the like), and/or other like materials; plastics and/or other like materials; composites and/or other like materials; metals, such as zinc, magnesium, titanium, copper, iron, steel, carbon steel, alloy steel, tool steel, stainless steel, spring steel, aluminum, and/or other like materials; and/or any combination of the foregoing.

Furthermore, embodiments of the present disclosure may be manufactured separately and then assembled together, or any or all of the components may be manufactured simultaneously and integrally joined with one another. Manufacture of these components separately or simultaneously, as understood by those of ordinary skill in the art, may involve 3-D printing, extrusion, pultrusion, vacuum forming, injection molding, blow molding, resin transfer molding, casting, forging, cold rolling, milling, drilling, reaming, turning, grinding, stamping, cutting, bending, welding, soldering, hardening, riveting, punching, plating, and/or the like. If any of the components are manufactured separately, they may then be coupled or removably coupled with one another in any manner, such as with adhesive, a weld, a fastener, any combination thereof, and/or the like for example, depending on, among other considerations, the particular material(s) forming the components.

In places where the description above refers to particular implementations, it should be readily apparent that a number of modifications may be made without departing from the spirit thereof and that these implementations may be applied to other implementations disclosed or undisclosed. The presently disclosed are, therefore, to be considered in all respects as illustrative and not restrictive.

What is claimed is:

1. A photocatalyst for CO2 reduction, comprising:
a plurality of nanoparticles, each nanoparticle comprising a plasmonic metal coupled to a semiconductor to form a nano-Janus heterostructure,
wherein an interface between the plasmonic metal and the semiconductor forms a Schottky junction.

2. The photocatalyst of claim 1, wherein the plasmonic metal comprises gold.

3. The photocatalyst of claim 1, wherein the semiconductor comprises cuprous oxide (Cu₂O).

4. The photocatalyst of claim 1, wherein the interface between the plasmonic metal and the semiconductor is planar.

5. The photocatalyst of claim 1, wherein the interface between the plasmonic metal and the semiconductor is curved.

6. The photocatalyst of claim 1, wherein the nanoparticles have a geometry selected from spherical, cubic, and dodecahedral.

7. A system for CO₂ reduction, comprising:
a reactor chamber configured to receive CO₂ and light energy; and
a photocatalyst disposed within the reactor chamber, the photocatalyst comprising a plurality of nanoparticles, each nanoparticle including a plasmonic metal portion coupled to a semiconductor portion to form a nano-Janus heterostructure with a Schottky junction at an interface between the plasmonic metal portion and the semiconductor portion.

8. The system of claim 7, wherein the photocatalyst comprises a substrate configured to orient the nanoparticles in a predetermined direction.

9. The system of claim 7, wherein the nanoparticles are embedded in a porous matrix that maintains alignment of the plasmonic metal portion and the semiconductor portion.

10. The system of claim 7, wherein the photocatalyst comprises a substrate having surface features that orient the nanoparticles.

11. The system of claim 10, wherein the nanoparticles are oriented in the same direction.

12. The system of claim 10, wherein the substrate includes a conductive layer configured to electrically couple to the plasmonic metal portions of the nanoparticles.

13. The system of claim 10, wherein the nanoparticles are immobilized on the substrate using a ligand-based anchoring system that preserves the nano-Janus configuration.

14. The system of claim 7, wherein the photocatalyst comprises a three-dimensional scaffold configured to support the nanoparticles in multiple orientations.

15. A method for fabricating a photocatalyst for CO2 reduction, the method comprising:
tuning a surface energy of a plurality of plasmonic metal nanoscale seeds through ligand incubation;
depositing a semiconductor on part of each seed; and
growing the semiconductor on the seed through selective nucleation informed by the ligand incubation.

16. The method of claim 15, wherein the plasmonic metal comprises gold (Au).

17. The method of claim 15, wherein the semiconductor comprises cuprous oxide (Cu₂O).

18. The method of claim 15, wherein tuning the surface energy of the plasmonic metal nanoscale seeds comprises exposing the seeds to a thiol-based ligand solution.

19. The method of claim 15, wherein depositing the semiconductor comprises solution-phase deposition.

20. The method of claim 15, wherein the semiconductor material is deposited on a portion of each seed such that the semiconductor material grows selectively on the seed to form a nano-Janus heterostructure.
